(19) United States
(12) Patent Application Publication
(10) Pub. No.: US 2008/0218244 A1
(43) Pub. Date: Sep. 11, 2008

(54) Analog switch

(75) Inventors: Kazuaki Oishi, Kawasaki (JP); Masahiro Kudo, Kawasaki (JP)

Correspondence Address: HANIFY & KING PROFESSIONAL CORPORATION, 1875 K STREET, NW, SUITE 707, WASHINGTON, DC, 20006, US

(73) Assignee: FUJITSU LIMITED

(21) Appl. No.: 12/073,337

(22) Filed: Mar. 4, 2008

(30) Foreign Application Priority Data
Mar. 5, 2007 (JP) JP2007-054934

(51) Int. Cl. H03K 17/16

(52) U.S. Cl. 327/389

(57) ABSTRACT

An analog switch comprises a first transistor, a second transistor, the drain and the source thereof being connected between said first input terminal and a second output terminal whereto said second signal is output and the gate thereof being grounded or connected to a supply voltage node, a third transistor, the drain and the source thereof being connected between a second input terminal whereto said second signal is input and said second output terminal and said third transistor being turned on and off by a control signal provided to the gate thereof; and a fourth transistor, the drain and the source thereof being connected between said second input terminal and said first output terminal and the gate thereof being grounded or connected to a supply voltage node.

### 1. BACKGROUND

The present device relates to an analog switch formed in a semiconductor integrated circuit.

### 2. DESCRIPTION OF THE RELATED ART

An analog switch is used to transfer or block analog signals transmitted through signal lines in a semiconductor integrated circuit. It has become increasingly difficult to realize a high off-resistance in a circuit due to an increase in the off-state leakage current of a MOS transistor along with the miniaturization of a semiconductor integrated circuit. An increase in the off-state leakage current of an analog switch increases signal distortion in a post-stage amplifier.

FIG. 8 shows a single-end amplifier circuit 11, which controls the amplification gain by selecting a resistance value with analog switches.

Resistors R1 to Rn and n-channel MOS transistors TR1 to TRn functioning as analog switches are connected in series with the inverting input terminal of a single-end amplifier 12. A feedback resistor R0 is connected between the inverting input terminal and the output terminal of the single-end amplifier 12. A reference voltage is applied to the non-inverting input terminal. Control signals S1 to Sn are applied to the gates of the n-channel MOS transistors TR1 to TRn, and the on/off states of the analog switches are controlled by these control signals S1 to Sn.

In the above-mentioned single-end amplifier circuit 11, the off-state leakage current of the analog switches is large. Hence, if the off resistance of the analog switches is small, an input signal applied when the analog switches are off passes through the analog switches and the input signal is input to the inverting input terminal and amplified. Thus, the single-end amplifier circuit 11 has had the problem that signal distortion becomes large.

In order to reduce the off-state leakage current of an analog switch, there has been proposed such a T-switch as shown in FIG. 9.

This analog switch (T-switch) 21 comprises two n-channel MOS transistors TR11 and TR12 connected in series with a signal path and a p-channel MOS transistor TR13, the source of which is connected to a VDD/2 voltage node and the drain of which is connected to a connection point between the MOS transistors TR11 and TR12. A common control signal is provided to the gates of the MOS transistors TR11, TR12 and TR13, respectively.

Since an off-state leakage current flows in the direction indicated by an arrow shown in FIG. 9 in this analog switch 21, it is possible to reduce a leakage current output from an output terminal.

However, since the above-mentioned analog switch 21 is structured so that two MOS transistors are connected in series on a signal path, the on resistance of the analog switch 21 when the switch is turned on is doubled. In order to reduce the on resistance, this analog switch 21 requires that MOS transistors be connected in parallel and that four MOS transistors be provided in the signal path. Thus, the analog switch has had the problem that the device area increases.

Japanese Patent Laid-Open No. 62-281613 describes that a control signal component is removed from an output signal by equalizing DC output levels at the on and off states of an analog switch.

### 3. SUMMARY

Accordingly, it is an object of the present device to realize an analog switch having a lesser amount of leakage current by using n-channel MOS transistors in the analog switch. In order to achieve the aforementioned object, the analog switch in accordance with the present device comprises a first transistor, the drain and the source thereof being connected between a first input terminal whereto said first signal is input and a first output terminal whereto said first signal is output and said first transistor being turned on and off by a control signal provided to the gate thereof;

a second transistor, the drain and the source thereof being connected between said first input terminal and a second output terminal whereto said second signal is output and the gate thereof being grounded or connected to a supply voltage node;

a third transistor, the drain and the source thereof being connected between a second input terminal whereto said second signal is input and said second output terminal, and said third transistor being turned on and off by a control signal provided to the gate thereof; and

a fourth transistor, the drain and the source thereof being connected between said second input terminal and said first output terminal, and the gate thereof being grounded or connected to a supply voltage node.

### 4. BRIEF DESCRIPTION OF THE DRAWINGS

FIG. 1 shows a circuit diagram of an analog switch in accordance with a first embodiment;

FIG. 2A shows an explanatory diagram of the operation of the analog switch when the switch is in an on state;

FIG. 2B shows an explanatory diagram of the operation of the analog switch when the switch is in an off state;

FIG. 3 shows one example of an amplifier circuit;

FIG. 4 shows a circuit diagram of an analog switch in accordance with a second embodiment;

FIG. 5 shows a circuit diagram of an analog switch in accordance with a third embodiment;

FIG. 6 shows the results of simulation;

FIG. 7 shows a circuit diagram of an analog switch used for simulation;

FIG. 8 shows an amplifier circuit making use of a conventional analog switch; and

FIG. 9 shows a circuit diagram of the T-switch.

### 5. DETAILED DESCRIPTION OF THE EMBODIMENTS

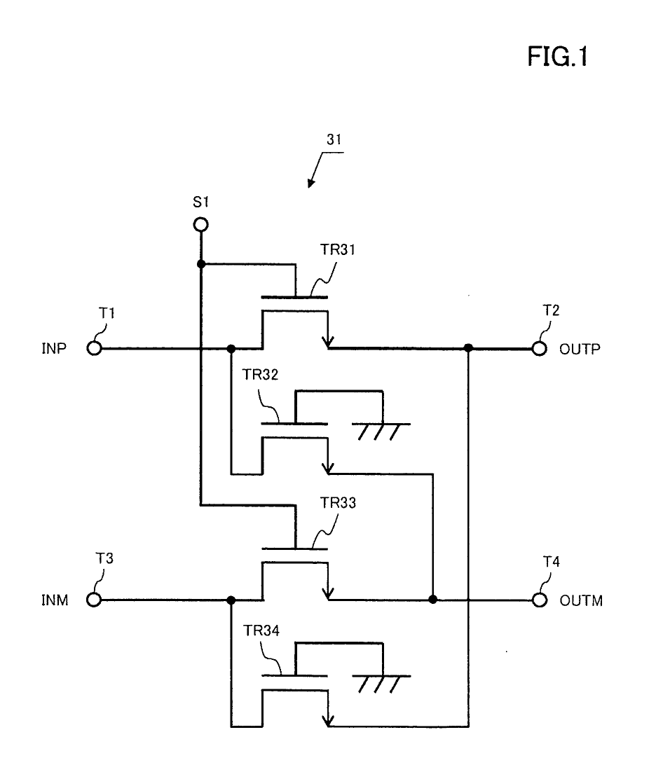

Hereinafter, embodiments of the present device will be described with reference to the drawings. FIG. 1 is a circuit diagram of an analog switch 31 in accordance with a first embodiment. This analog switch 31 is formed in a MOS integrated circuit or the like.

The analog switch 31 comprises four n-channel MOS transistors TR31 to TR34, wherein the MOS transistor TR31 and TR33 is controlled to turn on by control signal S1 and the MOS transistor TR32 and TR34 is off. Therefore, the analog switch 31 transfers or blocks an input signal.

The first input terminal T1 of the analog switch 31 is connected to a signal line whereto an input signal INP, which is one of differential signal, is input and the second input terminal T3 of the analog switch 31 is connected to a signal line whereto an inverted signal INM, which is an inversion of the input signal INP, is input. When the analog switch 31 is on, the first input signal INP is output from a first output terminal T2 as an output signal OUTP and the second input signal INM is output from a second output terminal T4 as an output signal OUTM.

In FIG. 1, the drain of the n-channel MOS transistor 31 (corresponds to a first transistor) is connected to the first input terminal T1 whereto the input signal INP is input, the source thereof is connected to the output terminal T2, and the gate thereof is provided with the control signal S1.

The drain of the n-channel MOS transistor TR32 (corresponds to a second transistor) is connected to the drain (connected to the first input terminal) of the MOS transistor TR31, the source thereof is connected to the source (connected to the second output terminal) of the n-channel MOS transistor TR33, and the gate thereof is grounded.

The drain of the n-channel MOS transistor TR33 (corresponds to a third transistor) is connected to the second input terminal T3 whereto the input signal INM is input, the source thereof is connected to the second output terminal T4, and the gate thereof is provided with the control signal S1.

The drain of the n-channel MOS transistor TR34 (corresponds to a fourth transistor) is connected to the drain (connected to the second output terminal) of the MOS transistor TR33, the source thereof is connected to the source (connected to the first output terminal) of the MOS transistor TR31, and the gate thereof is grounded.

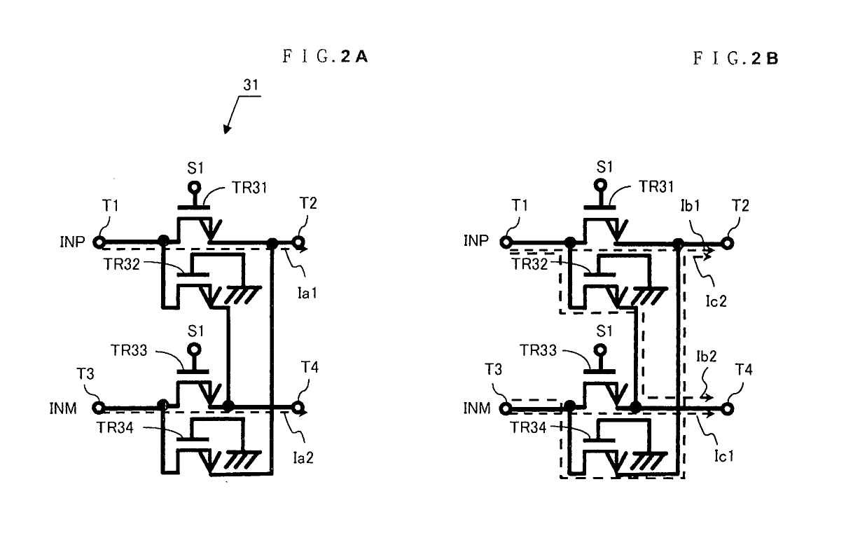

Next, the operation of the analog switch 31 will be described with reference to FIGS. 2A and 2B. FIG. 2A is an explanatory diagram of the operation of the analog switch 31 when the switch is in an on state and FIG. 2B is an explanatory diagram of the operation of the analog switch 31 when the switch is in an off state.

When the control signal S1 is higher than the gate threshold voltage of an n-channel MOS transistor, the MOS transistors TR31 and TR33 go to an on state. Since the gates of the MOS transistors TR32 and TR34 are grounded, the MOS transistors TR32 and TR34 are always in an off state. At this time, a current Ia1 flows through the MOS transistor TR31 according to the input signal INP and a current Ia2 flows through the MOS transistor TR33 according to the inverted signal INM, as shown in FIG. 2A.

When the control signal S1 is lower than the threshold voltage, the MOS transistors TR31 and TR33 go to an off state.

Now, consideration will be given to a leakage current with respect to the differential input signal INP. As shown in FIG. 2B, a leakage current Ib1 caused by the input signal INP flows through the MOS transistor TR31 when the transistor is off. Concurrently, a leakage current Ib2 caused by the input signal INP flows through the MOS transistor TR32. The leakage current Ib1 flows into the first output terminal T2, and the leakage current Ib2 flows into the second output terminal T4. By designing the MOS transistors TR31 and TR32 so as to share the same device size and provide the same characteristics, both transistors have almost the same magnitude of an off-state leakage current.

Consequently, a leakage current the same in phase and magnitude as the input signal INP flows through the output terminals T2 and T4. Therefore, it is possible to eliminate the common-mode component of the leakage current by amplifying the output voltages of the output terminals T2 and T4 with a differential amplifier and deriving a difference between the two output voltages.

The same holds true for a leakage current caused by the inverted signal INM. As shown in FIG. 2B, a leakage current Ic1 caused by the inverted signal INM flows from the MOS transistor TR33 toward the second output terminal T4. Concurrently, a leakage current Ic2 caused by the inverted signal INM flows from the MOS transistor TR34 toward the first output terminal T2. By designing the MOS transistors TR33 and TR34 so as to be the same device size and provide the same characteristics, both transistors have almost the same magnitude of an off-state leakage current.

Consequently, a leakage current of the same in phase and magnitude as the inverted signal INM flows through the output terminal T2 and the output terminal T4. Therefore, it is possible to eliminate the common-mode component of the leakage current by amplifying the output voltages of the output terminals T2 and T4 with a differential amplifier and deriving a difference between the two output voltages.

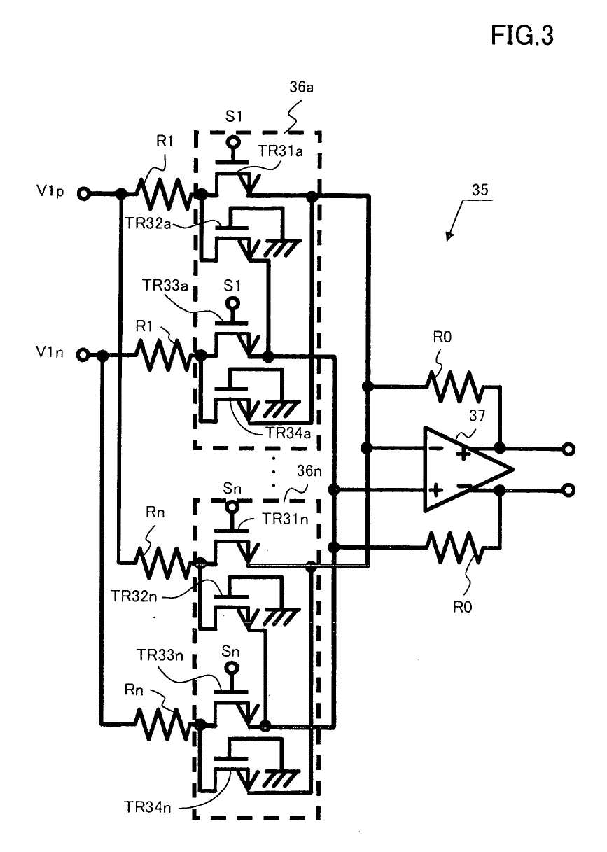

FIG. 3 shows one example of a differential amplifier circuit 35 making use of the analog switch 31 in accordance with the first embodiment.

This differential amplifier circuit 35 comprises a differential operational amplifier 37, n units of analog switches 36a to 36n, 2×n units of resistors R1 to Rn, and two feedback resistors R0.

The analog switches 36a to 36n have the same circuit configuration as that of the analog switch 31 shown in FIG. 1. Resistors R1 to Rn are connected to the input sides of the analog switches 36a to 36n and the output sides thereof are connected to the inverting and non-inverting input terminals of the differential operational amplifier 37. The feedback resistors R0 are connected between the differential output terminal of the differential operational amplifier 37 and the inverting input terminal and between the differential output terminal and the non-inverting input terminal.

A differential input voltage VlP is input to the drain of the n-channel MOS transistor TR31a of an analog switch 36a through a resistor R1. The gate of the MOS transistor TR31a is provided with a control signal S1 for turning on and off the analog switch 36a and the source thereof is connected to the inverting input terminal. When the analog switch 36a is on, the input voltage VlP is output to the inverting input terminal of the differential amplifier 37.

The drain of a MOS transistor TR32a is connected to the drain of the MOS transistor TR31a and the source of the MOS transistor TR32a is connected to the source (connected to the non-inverting input terminal) of the MOS transistor TR33a. The gate of the MOS transistor TR32a is grounded, and the MOS transistor TR32a is always in an off state.

An inverted voltage VlN, which is an inversion of the differential input voltage VlP, is provided to the drain of the MOS transistor TR33a through a resistor R1. The input voltage VlP(VlN [symbol] ?) is output from the source of the MOS transistor TR33a to the non-inverting input terminal of the differential operational amplifier 37. The control signal S1 is provided to the gate of the MOS transistor TR33a.

The drain of a MOS transistor TR34a is connected to the drain of the MOS transistor TR33a and the source of the MOS transistor TR34a is connected to the source (connected to the inverting input terminal) of the MOS transistor TR31a. The gate of the MOS transistor TR34a is grounded, and the MOS transistor TR34a is always in an off state.

Like the analog switch 36a, four-n-channel MOS transistors TR31n, TR32n, TR33n and TR34n are connected to the nth analog switch 36n.

In the above-described differential amplifier circuit 35, only the differential component of an input signal is amplified and the common-mode signal thereof is attenuated when the amplification gain of the differential amplifier circuit 35 is changed by varying the control signals S1 to Sn. Since all of the off-leakage currents of an analog switch in accordance with the present embodiment are common-mode components as is above-mentioned, a common-mode leakage current arising in the analog switch 31 is attenuated and thus the distortion of a differential signal can be reduced.

According to the above-mentioned first embodiment, the leakage currents of the MOS transistors flowing through the first and second output terminals T2 and T4 are made to be the same in phase and magnitude with each other by connecting the gate-grounded n-channel MOS transistors TR32 and TR34 between the first input terminal T1 and the second output terminal T4 and between the second input terminal T3 and the first output terminal T2, so as to cross each other.

Accordingly, by current-to-voltage converting and differentially amplifying the output current of the two output terminals T2 and T4 with a differential operational amplifier and deriving a difference between the two output voltages, only the differential component of the output current is amplified, and the common-mode leakage current thereof is attenuated. Since a leakage current arising in the analog switch 31 is a common-mode component and is, therefore, attenuated, it is possible to reduce the distortion of a differential signal.

Furthermore, since it is only necessary for the analog switch 31, in accordance with the first embodiment, to use two MOS transistors having a normal on resistance for each signal line (i.e., four MOS transistors for two signal lines), it is possible to reduce the device area of the analog switch 31, compared with a T-switch. In addition, since the size of transistors to be connected to a signal line can be reduced, the analog switch 31 can be used in circuits requiring high-speed operation.

The off-state leakage current of a MOS transistor tends to increase along with the advance in the miniaturization of semiconductor integrated circuits. However, it is possible to maintain the on resistance of an analog switch at a small value and suppress the off-state leakage current thereof by using the analog switch 31 in accordance with the above-described first embodiment, without having to significantly increase the device area.

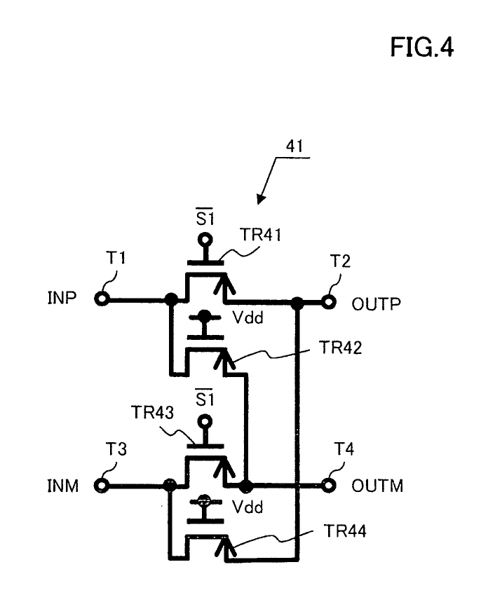

FIG. 4 is a circuit diagram of an analog switch 41 in accordance with a second embodiment. The second embodiment is an example wherein the analog switch 41 is configured using p-channel MOS transistors.

The analog switch 41 has four p-channel MOS transistors TR41 to TR44 and the on and off states of the MOS transistors TR41 and TR44 are controlled by a control signal /S1 (inversion of a control signal S1), thereby transferring or blocking an input signal.

An input signal INP, which is one differential signal, is input to the first input terminal T1 of the analog switch 41. When the analog switch 41 is on, the input signal is output from a first output terminal T2 as an output signal OUTP. An inverted signal INM, which is an inversion of the input signal INP, is input to the second input terminal T3 of the analog switch 41. The inverted signal INM is output from the second output terminal T4 as an output signal OUTM.

In FIG. 4, the drain of the p-channel MOS transistor TR41 is connected to the first input terminal T1 whereto the input signal INP is input, the source thereof is connected to the first output terminal T2, and the gate thereof is provided with the control signal /S1.

The drain of the p-channel MOS transistor TR42 is connected to the drain of the MOS transistor TR41, the source thereof is connected to the source of the p-channel MOS transistor TR33, and the gate thereof is connected to a supply voltage node Vdd.

The drain of the p-channel MOS transistor TR43 is connected to a second input terminal T3 whereto the inverted signal INM is input, the source thereof is connected to a second output terminal T4, and the gate thereof is provided with the control signal /S1.

The drain of the p-channel MOS transistor TR44 is connected to the drain of the MOS transistor TR43, the source thereof is connected to the source of the MOS transistor TR41, and the gate thereof is connected to the supply voltage node Vdd.

Next, the operation of the analog switch 41 shown in FIG. 4 will be described. When the control signal /S1 is lower than a gate threshold voltage, the p-channel MOS transistors TR41 and TR43 go to an on state. When the MOS transistors TR41 and TR43 go to an on state, an input signal INP and an inverted signal INM of the analog switch 41 are output from the first output terminal T2 and the second output terminal T4, respectively.

On the other hand, when the control signal /S1 is higher than the gate threshold voltage, the p-channel MOS transistors TR41 and TR43 go to an off state. At this time, the p-channel MOS transistors TR42 and TR44 are in an off state since the gates of these are connected to the supply voltage node Vdd.

When the MOS transistor TR41 is off, an off-state leakage current flows between the drain and the source of the MOS transistor TR41, and at the same time, a leakage current that is the same in magnitude as the off-state leakage current also flows through the MOS transistor TR42. That is, a leakage current flows from the MOS transistor TR41 toward the first output terminal T2 and, at the same time, a leakage current that is the same in phase and magnitude as the above-mentioned leakage current flows from the MOS transistor TR42 toward the second output terminal T4.

Consequently, a leakage current that is the same in phase and magnitude as the input signal INP flows into the output terminals T2 and T4, respectively. Therefore, it is possible to eliminate the common-mode component of the leakage current caused by the input signal INP by current-to-voltage converting and amplifying the output current of the output terminals T2 and T4 with a differential operational amplifier and deriving a difference between the two output voltages.

The same holds true for a leakage current caused by the inverted signal INM. When the MOS transistor TR43 is in an off state, the MOS transistor TR44 connected to the first output terminal T4 is also in an off state. The off-state leakage current of the MOS transistor TR43 flows into the second output terminal T4 and the leakage current of the MOS transistor TR44 flows into the first output terminal T2.

Consequently, a leakage current that is the same in phase and magnitude as the input signal INM flows into the output terminals T2 and T4. Therefore, it is possible to eliminate the common-mode component of the leakage current by current-to-voltage converting and amplifying the output current of the output terminals T2 and T4 with a differential operational amplifier and deriving a difference between the two output voltages.

According to the above-mentioned second embodiment, the leakage currents of the gate connected to Vdd p-channel MOS transistors TR42 and TR44 in the analog switch flowing through the first and second output terminals T2 and T4 are made to be the same in phase and magnitude with each other by respectively connecting the MOS transistors TR42 and TR44 between the first input terminal T1 and the second output terminal T4 and between the second input terminal T3 and the first output terminal T2, so as to cross each other.

Accordingly, by current-to-voltage converting and differentially amplifying the output current of the two output terminals T2 and T4 with a differential operational amplifier and deriving a difference between the two output voltages, only the differential component of the output current is amplified and, therefore, the common-mode leakage current thereof is attenuated. Since the leakage currents of the MOS transistors are all common-mode components, a common-mode leakage current arising in the analog switch 31 is attenuated. Thus, it is possible to reduce the distortion of a differential signal.

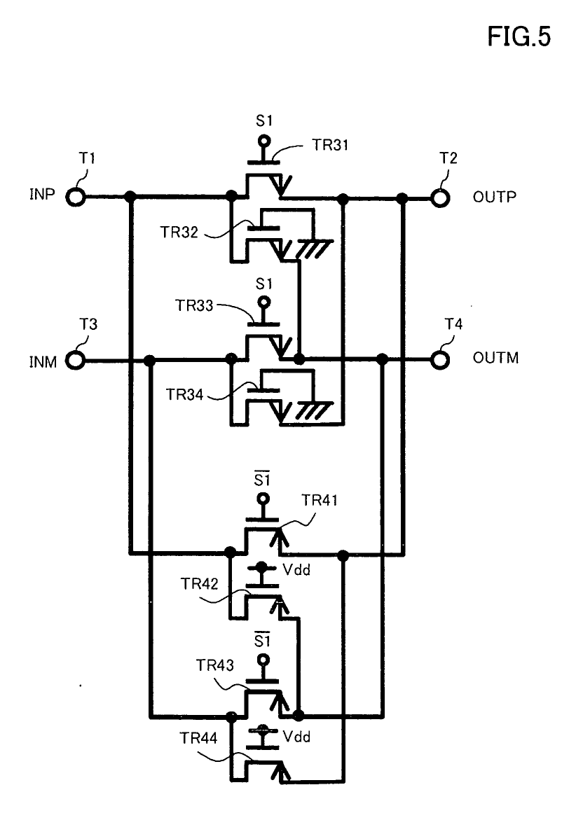

FIG. 5 is a circuit diagram of an analog switch 51 in accordance with a third embodiment. The third embodiment is an example wherein an analog switch is configured by connecting p-channel and n-channel MOS transistors in parallel.

In FIG. 5, n-channel MOS transistors TR31, TR32, TR33 and TR34 are connected in the same manner as in the analog switch 31 shown in FIG. 1, and the same voltage is applied to the gates of these MOS transistors. Likewise, p-channel MOS transistors TR41, TR42, TR43 and TR44 are connected in the same manner as in the analog switch 41 shown in FIG. 4, and the same voltage is applied to the gates of these MOS transistors.

Now, the off-state operation of an analog switch 51 will be described.

First, an explanation will be made of a leakage current caused by an input signal INP. When control signals S1 drop below a gate threshold voltage and /S1 raise above a gate threshold voltage, the n-channel MOS transistor TR31 and the p-channel MOS transistor TR41 go to an off state (off state of the analog switch 51). At this time, the n-channel MOS transistor TR32 and the p-channel MOS transistor TR42 connected between the first input terminal T1 and the second output terminal T4 are in an off state.

When the analog switch 51 is in an off state, a given leakage current flows between the drains and the sources of the MOS transistors TR31 and TR41. Thus, a leakage current the same in phase and magnitude as the above-mentioned given leakage current flows between the drains and the sources of the MOS transistors TR32 and TR42 cross-connected between the first input terminal T1 and the second output terminal T4.

Consequently, a leakage current the same in phase and magnitude as the input signal INP flows into the output terminals T2 and T4, respectively. Therefore, it is possible to eliminate the common-mode component of the leakage current caused by the input signal INP by current-to-voltage converting and amplifying the output current of the first and second output terminals T2 and T4 with a differential operational amplifier and deriving a difference between the two output voltages.

The same holds true for a leakage current caused by the inverted signal INM. When the n-channel MOS transistor TR33 and the p-channel MOS transistor TR43 go to an off state, the n-channel MOS transistor TR34 and the p-channel MOS transistor TR44 connected between the second input terminal T3 and the first output terminal T4 so as to cross each other also go to an off state.

When the analog switch 51 is in an off state, a given leakage current flows between the drains and the sources of the MOS transistors TR33 and TR43. Thus, a leakage current the same in phase and magnitude as the aforementioned given leakage current flows between the drains and the sources of the n-channel MOS transistors TR34 and the p-channel MOS transistor TR44 cross-connected between the second input terminal T3 and the first output terminal T2.

Consequently, a leakage current the same in phase and magnitude as the inverted signal INM flows into the first and second output terminals T2 and T4. Therefore, it is possible to eliminate the common-mode component of the leakage current caused by the inverted signal INM by current-to-voltage converting and amplifying the output current of the first and second output terminals T2 and T4 with a differential operational amplifier and deriving a difference between the two output voltages.

Lastly, an explanation will be made of the results of comparison in the input-output characteristics of a differential amplifier circuit between a case where an analog switch in accordance with an embodiment of the present invention is used and a case where a conventional analog switch is used.

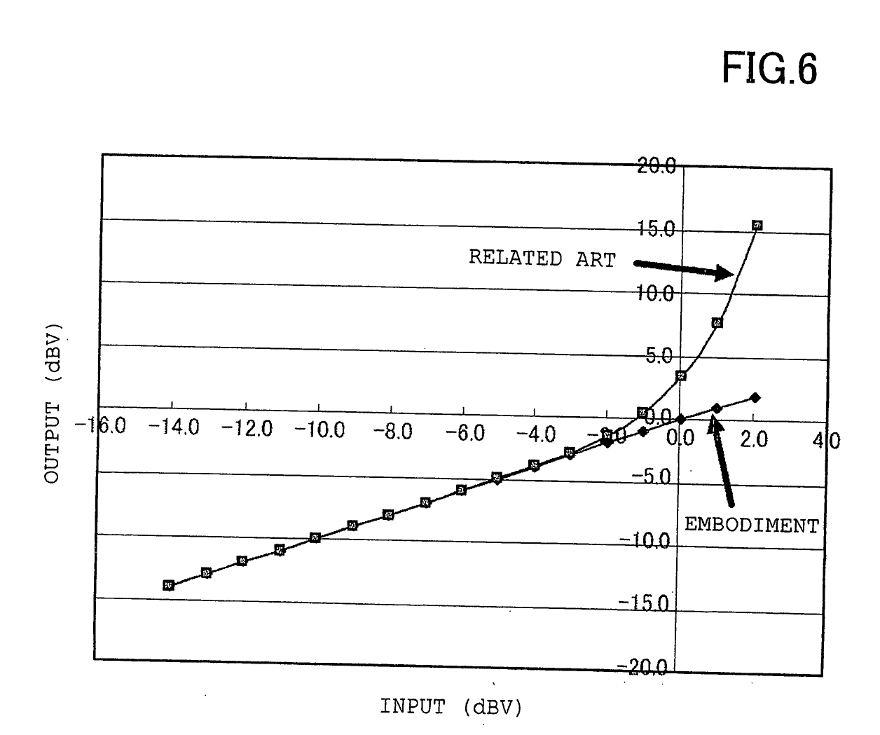

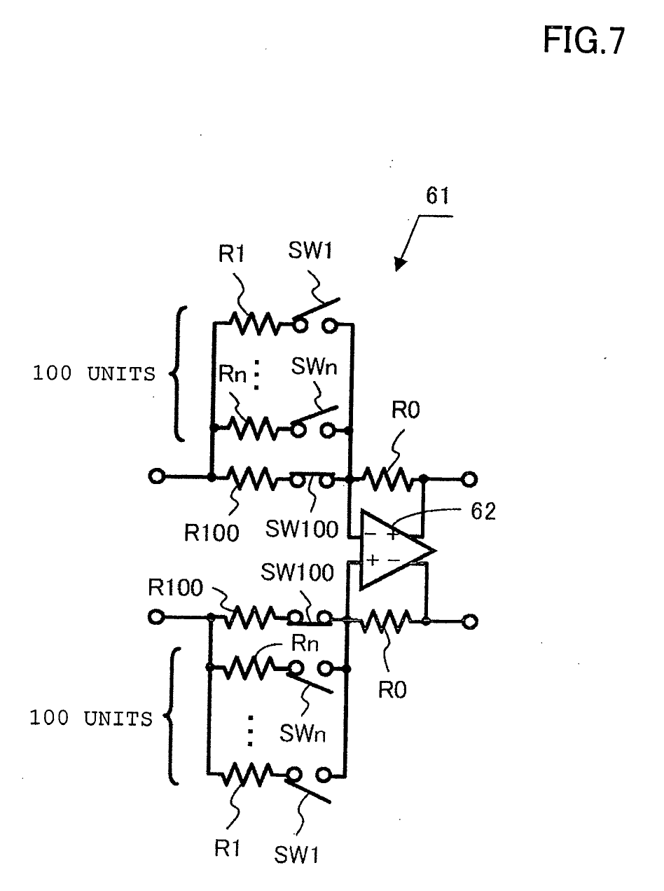

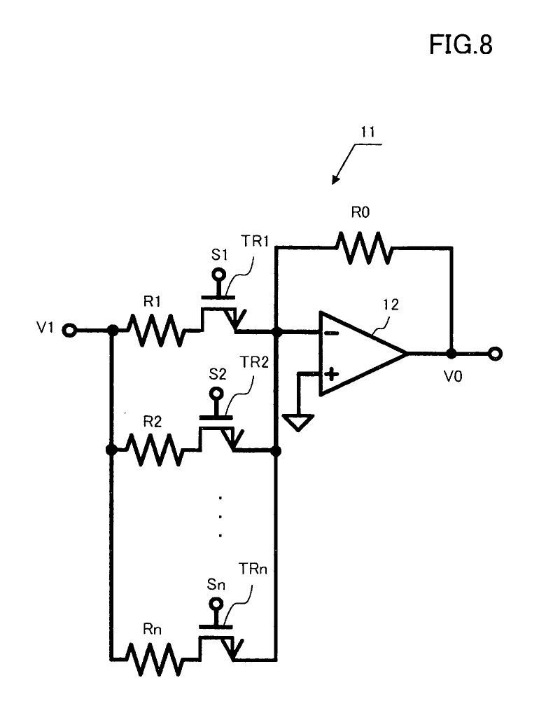

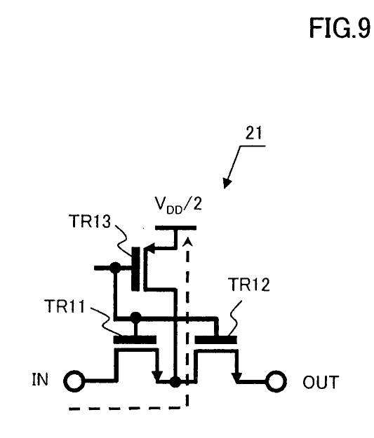

FIG. 6 is a graphical view showing the result of simulating input-output characteristics when the conventional analog switch and the analog switch 31 in accordance with an embodiment of the present invention are used. The axis of abscissa shown in FIG. 6 denotes the dBV value of an input level (dB value based on 1 V) and the axis of ordinate denotes the dBV value of an output level. The simulation was carried out using a differential amplifier circuit 61 shown in FIG. 7.

In the differential amplifier circuit 61 shown in FIG. 7, 100 units of analog switches SW1 to SW100 are connected to each of the inverting input terminal and the non-inverting input terminal of an ideal operational amplifier 62 and the amplification gain of the differential amplifier circuit 61 is controlled by switching these analog switch SW1 to SW100.

As shown in FIG. 6, the output dBV value of a differential amplifier circuit making use of the conventional analog switch drastically increases from a point near an input dBV value of −1 dBV. In contrast, the output dBV value of the differential amplifier circuit 61 making use of the analog switch in accordance with an embodiment of the present invention varies linearly in response to a change in the input dBV value.

The reason that the output level of the differential amplifier circuit 61 making use of the conventional analog switch shows nonlinearity is that the off-state leakage current of the conventional analog switch increases as the input level thereof becomes higher and, consequently, the signal distortion of the differential amplifier circuit increases. From the simulation results shown in FIG. 6, it was confirmed that the differential component of a leakage current was suppressed by the analog switch 31 in accordance with an embodiment of the present invention and the like and, consequently, the output signal distortion of the differential amplifier circuit reduced.

According to the above-described embodiment, since the leakage currents of MOS transistors flowing into the differential signal output terminals thereof are the same in phase and magnitude with each other, no differential components exist in the leakage currents. The differential signal of the analog switch does not become distorted even if the voltages of the two output terminals are differentially amplified with a differential amplifier and converted to differential voltages. The off-state leakage currents of the analog switches are attenuated at the differential amplifier.

The present device is not limited to the above-described embodiments but may be configured, for example, in the following manners: (1) In the above-mentioned embodiments, a ground potential or a supply voltage is applied to the gates of the n-channel MOS transistors TR32 and TR34 or to the gates of the p-channel MOS transistors TR42 and TR44. Alternatively, a voltage higher or lower than the ground potential or the supply voltage may be applied as long as the voltage is a gate voltage capable of turning off the MOS transistors. (2) The analog switch in accordance with the present device is applicable not only to the differential amplifier circuit described in the embodiments but also to differential amplifier circuits heretofore known. In addition, the present device may be used as an analog switch for a switched-capacitor circuit.

What is claimed is:

1. An analog switch adapted to transfer or block a first signal of a differential signal and a second signal, which is an inversion of said first signal, said analog switch comprising:
a first transistor, a drain and a source thereof being connected between a first input terminal whereto said first signal is input and a first output terminal whereto said first signal is output and said first transistor being turned on and off by a control signal provided to a gate thereof;
a second transistor, a drain and a source thereof being connected between said first input terminal and a second output terminal whereto said second signal is output and a gate thereof being grounded or connected to a supply voltage node;
a third transistor, a drain and a source thereof being connected between a second input terminal whereto said second signal is input and said second output terminal and said third transistor being turned on and off by a control signal provided to a gate thereof; and
a fourth transistor, a drain and a source thereof being connected between said second input terminal and said first output terminal and a gate thereof being grounded or connected to a supply voltage node.

2. The analog switch according to claim 1, wherein said first transistor, said second transistor, said third transistor and said fourth transistor are n-channel MOS transistors and the gates of said second transistor and said fourth transistor are grounded.

3. The analog switch according to claim 1, wherein said first transistor, said second transistor, said third transistor and said fourth transistor are p-channel MOS transistors and the gates of said second transistor and said fourth transistor are connected to a supply voltage node.

4. The analog switch according to claim 1, wherein said first transistor, said second transistor, said third transistor and said fourth transistor are n-channel MOS transistors, the drain of said first transistor being connected to said first input terminal, the source thereof being connected to said first output terminal, the drain of said second transistor being connected to said first input terminal, the source thereof being connected to said second output terminal, the gate thereof being grounded, the drain of said third transistor being connected to said second input terminal, the source thereof being connected to said second output terminal, the drain of said fourth transistor being connected to said second input terminal, the source thereof being connected to said first output terminal, and the gate thereof being grounded.

5. The analog switch according to claim 1, wherein said first transistor, said second transistor, said third transistor and said fourth transistor are p-channel MOS transistors, the drain of said first transistor being connected to said first input terminal, the source thereof being connected to said first output terminal, the drain of said second transistor being connected to said first input terminal, the source thereof being connected to said second output terminal, the gate thereof being connected to a supply voltage node, the drain of said third transistor being connected to said second input terminal, the source thereof being connected to said second output terminal, the drain of said fourth transistor being connected to said second input terminal, the source thereof being connected to said first output terminal, and the gate thereof being connected to a supply voltage node.

6. An analog switch having p-channel and n-channel MOS transistors connected in parallel and adapted to transfer or block a first signal of a differential signal and a second signal, which is an inversion of said first signal, said analog switch comprising:
a first n-channel MOS transistor, a drain and a source thereof being connected between a first input terminal whereto said first signal is input and a first output terminal whereto said first signal is output and said first n-channel MOS transistor being turned on and off by a control signal provided to a gate thereof;
a second n-channel MOS transistor, a drain and a source thereof being connected between said first input terminal and a second output terminal whereto said second signal is output and a gate thereof being grounded;
a third n-channel MOS transistor, a drain and a source thereof being connected between a second input terminal whereto said second signal is input and said second output terminal and said third n-channel MOS transistor being turned on and off by a control signal provided to a gate thereof;
a fourth n-channel MOS transistor, a drain and a source thereof being connected between said second input terminal and said first output terminal and a gate thereof being grounded;
a first p-channel MOS transistor, a drain and a source thereof being connected between said first input terminal and said first output terminal and said first p-channel MOS transistor being turned on and off by an inverted control signal provided to a gate thereof;
a second p-channel MOS transistor, a drain and a source thereof being connected between said first input terminal and said second output terminal and a gate thereof being connected to a supply voltage node;
a third p-channel MOS transistor, a drain and a source thereof being connected between said second input terminal and said second output terminal and said third p-channel MOS transistor being turned on and off by an inverted control signal provided to a gate thereof; and
a fourth p-channel MOS transistor, a drain and a source thereof being connected between said second input terminal and said first output terminal and a gate thereof being connected to a supply voltage node.
